(19) United States
(12) Patent Application Publication
(10) Pub. No.: US 2026/0157101 A1
(43) Pub. Date: Jun. 4, 2026

(54) DISPLAY APPARATUS

(71) Applicant: LG Display Co., Ltd., Seoul (KR)

(72) Inventors: SungSik Son, Daegu (KR); JunHyeong Lee, Gumi-si (KR)

(73) Assignee: LG Display Co., Ltd., Seoul (KR)

(21) Appl. No.: 19/211,051

(22) Filed: May 16, 2025

(30) Foreign Application Priority Data
Nov. 29, 2024 (KR) 10-2024-0175484

(51) Int. Cl. H10K 59/80; B60K 37/10

(52) U.S. Cl. CPC H10K 59/8794; B60K 37/10; H10K 59/8722; B60K 2360/816

(57) ABSTRACT

A display apparatus includes a display panel, a heat dissipation sheet on the display panel, a shield can on the heat dissipation sheet, and a set cover on the shield can. The heat dissipation sheet includes a sheet portion and a first insertion portion protruding from the sheet portion toward the set cover and coupled with the shield can. The shield can includes a base portion having a flat shape, and a plurality of extension portions including a first portion extending in a first direction from the base portion toward the heat dissipation sheet and a second portion extending in a second direction from the first portion. At least one of the plurality of extension portions includes a first hole into which the first insertion portion is inserted. A portion of the first insertion portion passing through the first hole is on the second portion.

### CROSS-REFERENCE TO RELATED APPLICATIONS

This application claims the priority of Korean Patent Application No. 10-2024-0175484 filed on Nov. 29, 2024, in the Korean Intellectual Property Office, the disclosure of which is incorporated herein by reference.

### BACKGROUND

### Technical Field

The present disclosure relates to a display apparatus and more particularly, to a circular display apparatus.

### Discussion of the Related Art

As display apparatus which are used for a monitor of a computer, a television, a cellular phone, or the like, there are an organic light emitting display (OLED) apparatus which is a self-emitting apparatus, a liquid crystal display (LCD) apparatus which requires a separate light source, and the like.

An applicable range of the display apparatus is diversified to personal digital assistants as well as monitors of computers and televisions and a display apparatus with a large display area and a reduced volume and weight is being studied. Further, recently, research is being conducted on a display apparatus having various shapes. For example, research is being conducted on a circular display apparatus.

### SUMMARY

Accordingly, embodiments of the present disclosure are directed to a display apparatus that substantially obviates one or more of the problems due to limitations and disadvantages of the related art.

An aspect of the present disclosure is to provide a display apparatus with improved fixing force.

Another aspect of the present disclosure is to provide a display apparatus capable of suppressing incorrect assembly.

Still another aspect of the present disclosure is to provide a display apparatus that may suppress lifting of the display apparatus due to a narrow fastening space.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display apparatus comprises a display panel, a heat dissipation sheet disposed on the display panel, a shield can disposed on the heat dissipation sheet, and a set cover disposed on the shield can, wherein the heat dissipation sheet includes a sheet portion and a first insertion portion protruding from the sheet portion toward the set cover and coupled with the shield can, the shield can includes a base portion having a flat shape, and a plurality of extension portions including a first portion extending in a first direction from the base portion toward the heat dissipation sheet and a second portion extending in a second direction different from the first direction from the first portion, at least one of the plurality of extension portions includes a first hole into which the first insertion portion is inserted, and a portion of the first insertion portion passing through the first hole is disposed on the second portion.

In another aspect, a display apparatus comprises a display panel, a heat dissipation sheet disposed on the display panel and including a first insertion portion, a printed circuit board electrically connected to the display panel and disposed on the heat dissipation sheet, a shield can disposed on the printed circuit board and including a first hole into which the first insertion portion is inserted, and a set cover disposed on the shield can, wherein at least a portion of the first insertion portion extends onto the shield can and overlaps a portion of the shield can.

Other detailed matters of the exemplary embodiments are included in the detailed description and the drawings.

The present disclosure may suppress incorrect assembly of the display apparatus by disposing a guide protrusion on the circular set cover.

The present disclosure enables a display panel to be fastened to the set cover through the heat dissipation sheet and the shield can, thereby improving the fixing force of the display apparatus even in a narrow space.

The present disclosure may improve the fixing force by inserting the heat dissipation sheet into the set cover.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a view illustrating a apparatus to which a display apparatus according to one exemplary embodiment of the present disclosure is applied;

FIG. 2 is a rear view of the display apparatus according to one exemplary embodiment;

FIG. 3 is an exploded perspective view of the display apparatus according to one exemplary embodiment of the present disclosure;

FIG. 4 is a view of a portion of the configuration of the display apparatus according to one exemplary embodiment of the present disclosure;

FIG. 5 is an exploded perspective view of the others of the configuration of the display apparatus according to one exemplary embodiment of the present disclosure;

FIG. 6 is a cross-sectional view of the display apparatus according to one exemplary embodiment of the present disclosure;

FIG. 7 is an enlarged view of an area A of FIG. 6;

FIG. 8 is an exploded perspective view of a display apparatus according to another exemplary embodiment of the present disclosure; and

FIG. 9 is a cross-sectional view of the display apparatus according to another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, an exemplary embodiment of the present disclosure will be described in detail with reference to the drawings.

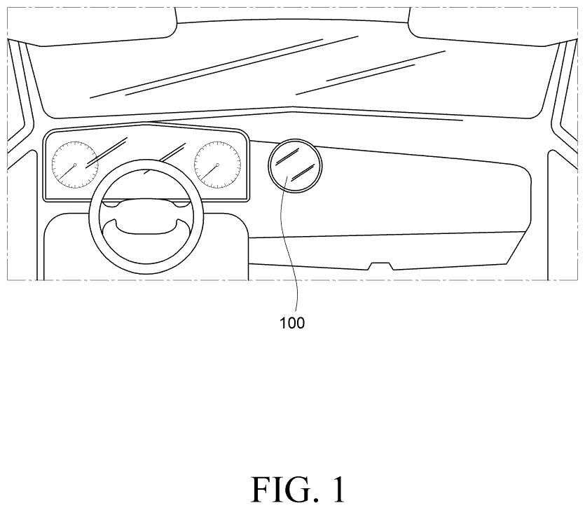

FIG. 1 is a view illustrating a apparatus to which a display apparatus according to one exemplary embodiment of the present disclosure is applied.

A display apparatus 100 may be disposed in at least a portion of a dashboard of a vehicle. The dashboard of the vehicle includes a configuration that is disposed in front of the front seats (for example, driver's seat, passenger seat) of the vehicle. For example, the dashboard of the vehicle may have input configurations disposed for operating various functions (for example, air conditioning, audio system, navigation system) inside the vehicle.

In the display apparatus 100 according to one exemplary embodiment of the present disclosure, the display apparatus 100 may be disposed on the dashboard of the vehicle and may function as an input unit for operating at least some of various functions of the vehicle. The display apparatus 100 may provide various information related to the vehicle, for example, operating information (for example, current speed of the vehicle, remaining fuel amount, driving distance) of the vehicle, and information on parts of the vehicle (for example, damage to vehicle tires).

The display apparatus 100 may be disposed across the driver's seat and the passenger seat located in the front seats of the vehicle. Users of the display apparatus 100 may include the driver of the vehicle and the passenger riding in the passenger seat. Both the driver and the passenger of the vehicle may use the display apparatus 100.

In the display apparatus 100 illustrated in FIG. 1, only a portion thereof is illustrated. The display apparatus 100 illustrated in FIG. 1 may illustrate a display panel among various components included in the display apparatus 100. Specifically, for example, the display apparatus 100 illustrated in FIG. 1 may illustrate at least a portion of a display area and a non-display area of the display panel. Components of the display apparatus 100 other than the parts illustrated in FIG. 1 may be mounted inside (or at least a portion of) the vehicle.

Referring to FIG. 1, the display apparatus 100 may be implemented in a circular shape to improve aesthetics. However, the present disclosure is not limited thereto, and the display apparatus 100 may be implemented in an oval shape or may be implemented in a polygonal shape.

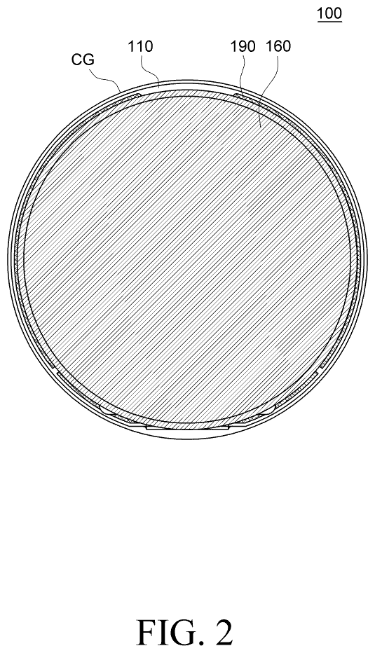

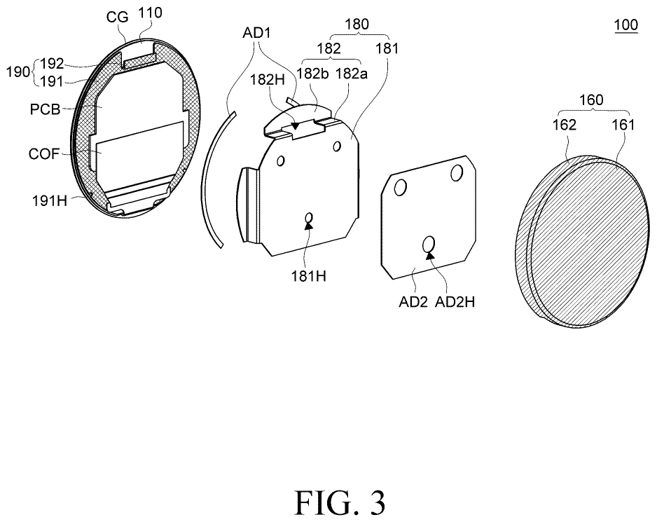

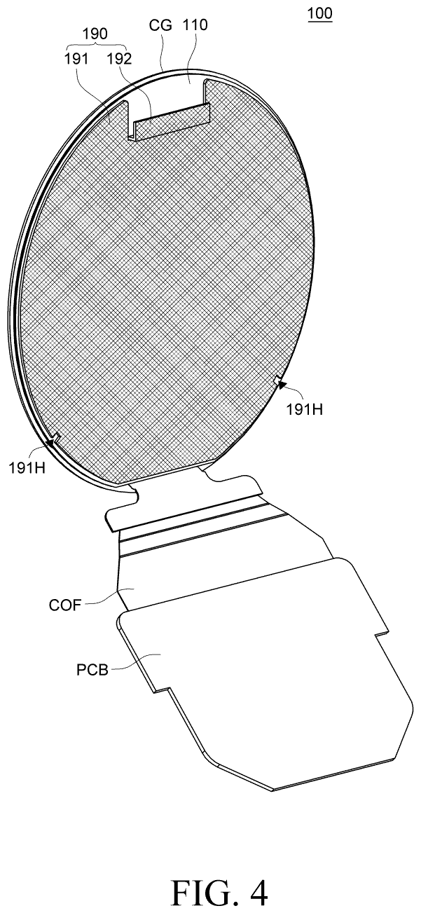

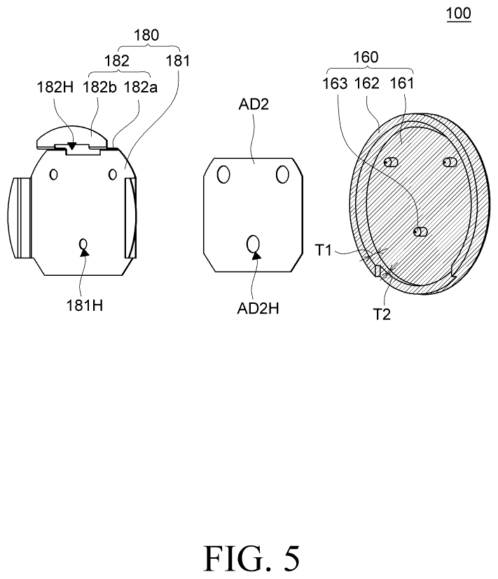

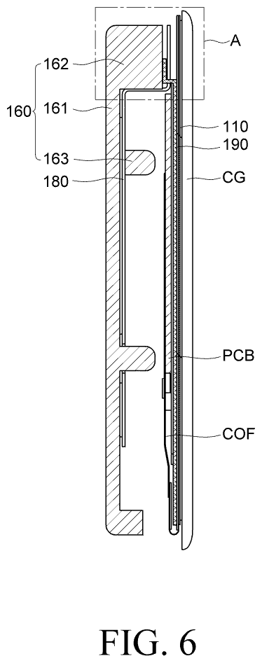

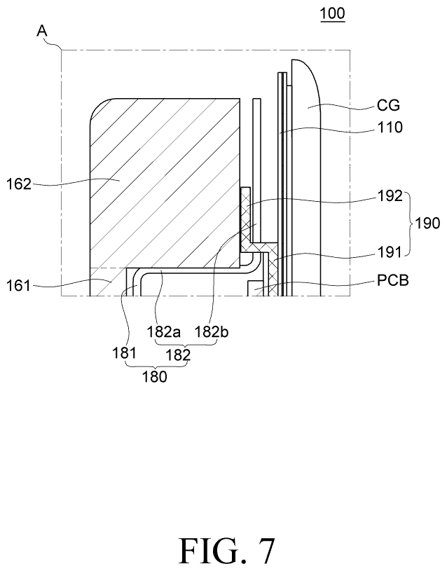

FIG. 2 is a rear view of the display apparatus according to one exemplary embodiment. FIG. 3 is an exploded perspective view of the display apparatus according to one exemplary embodiment of the present disclosure. FIG. 4 is a view of a portion of the configuration of the display apparatus according to one exemplary embodiment of the present disclosure. FIG. 5 is an exploded perspective view of the others of the configuration of the display apparatus according to one exemplary embodiment of the present disclosure. FIG. 6 is a cross-sectional view of the display apparatus according to one exemplary embodiment of the present disclosure. FIG. 7 is an enlarged view of an area A of FIG. 6.

Referring to FIGS. 2 to 7, the display apparatus 100 according to one exemplary embodiment of the present disclosure includes a cover glass CG, a display panel 110, a heat dissipation sheet 190, a shield can 180, a printed circuit board PCB, a flexible circuit film COF, and a set cover 160.

Referring to FIGS. 3 and 4, the cover glass CG may be disposed on the other surface of the display panel 110. The cover glass CG may have a shape corresponding to the display panel 110 and may be disposed to cover the other surface of the display panel 110. For example, the cover glass CG may have a circular shape corresponding to the display panel 110. The cover glass CG may protect the display panel 110 from external impact, moisture, heat, or the like.

Although not illustrated in the drawings, an adhesive member may be disposed between the display panel 110 and the cover glass CG. Accordingly, the display panel 110 and the cover glass CG may be attached to each other through the adhesive member.

The display panel 110 may be disposed on one surface of the cover glass CG. The display panel 110 is a panel for displaying an image to a user. A light-emitting diode for displaying an image, a driving element for driving the light-emitting diode, a wire for transmitting various signals to the light-emitting diode and the driving element, or the like may be disposed on the display panel 110.

The light-emitting diode may be defined differently depending on the type of the display panel 110. For example, when the display panel 110 is an organic light-emitting display panel, the light-emitting diode may be an organic light-emitting diode including an anode, an organic light-emitting layer, and a cathode. In the following description, it is assumed that the display panel 110 is an organic light-emitting display panel, but the display panel 110 is not limited to an organic light-emitting display panel.

The display panel 110 may include the display area and the non-display area.

The display area is an area where an image is displayed on the display panel 110. A plurality of sub-pixels constituting a plurality of pixels and a driving circuit for driving the plurality of sub-pixels may be disposed in the display area. The plurality of sub-pixels is the minimum units constituting the display area, and a display element may be disposed in each of the plurality of sub-pixels. For example, an organic light-emitting diode including an anode, an organic light-emitting layer, and a cathode may be disposed in each of the plurality of sub-pixels, but is not limited thereto. In addition, the driving circuit for driving the plurality of sub-pixels may include a driving element, a wire, or the like. For example, the driving circuit may be composed of a thin film transistor, a storage capacitor, a gate wire, a data wire, or the like, but is not limited thereto.

The non-display area is an area where no image is displayed. Various wires and circuits for driving the organic light-emitting diodes of the display area may be disposed in the non-display area.

The non-display area may include a pad area.

The pad area is an area where a plurality of pads is disposed. The plurality of pads is electrodes for electrically connecting the flexible circuit film COF and the display panel 110, and the flexible circuit film COF and the display panel 110 may be electrically connected through the plurality of pads.

The flexible circuit film COF is bonded to the other surface of the display panel 110. For example, the flexible circuit film COF may be connected to one side (for example, a lower side as shown in FIG. 3) of the display panel 110. The flexible circuit film COF is a film that supplies signals to display elements and circuits by disposing various components on a flexible base film, and may be electrically connected to the display panel 110. The flexible circuit film COF may supply power voltage, data voltage, or the like to the display panel 110. As illustrated in FIGS. 3 and 4, one flexible circuit film COF may be bonded to the display panel 110 in consideration of the area of the display panel 110. However, the present disclosure is not limited thereto, and a plurality of flexible circuit films COF may be bonded to the display panel 110, and the number and disposition of the flexible circuit films COF may be variously changed depending on the design.

A driver IC such as a gate driver IC, a data driver IC, or the like may be disposed on a flexible circuit film COF. The driver IC is a component that processes data for displaying an image and a driving signal for processing the data. Depending on the mounting method, the driver IC may be disposed in the method such as a chip on glass (COG), a chip on film (COF), or a tape carrier package (TCP). In the present disclosure, the chip on film method is described in which the driver IC is mounted on the flexible circuit film COF, but is not limited thereto.

Referring to FIGS. 3 and 4, the flexible circuit film COF may be bent at one side of the display panel 110 and disposed on one surface of the heat dissipation sheet 190. For example, one side of the flexible circuit film COF may be disposed on the other surface of the display panel 110, and the other side of the flexible circuit film COF may be disposed on one surface of the display panel 110 and one surface of the heat dissipation sheet 190.

The printed circuit board PCB is electrically connected to the flexible circuit film COF. The printed circuit board PCB is a component that supplies signals to the driver IC. Various components for supplying various signals, such as a driving signal and a data signal, to the driver IC may be disposed on the printed circuit board PCB. Meanwhile, although FIG. 3 and FIG. 4 illustrate that there is one printed circuit board PCB, the number of printed circuit boards PCBs may vary depending on the design and is not limited thereto.

Referring to FIGS. 3 and 4, the heat dissipation sheet 190 is disposed on one surface of the display panel 110. The heat dissipation sheet 190 may include a sheet portion 191 and a first insertion portion 192.

The sheet portion 191 may be attached to the display panel 110 by being disposed in a shape corresponding to one surface of the display panel 110. Accordingly, the sheet portion 191 may support and protect the display panel 110. In addition, the sheet portion 191 may function as a heat dissipation member that dissipates heat generated when the display apparatus 100 is driven.

The sheet portion 191 may include a plurality of grooves 191H. The plurality of grooves 191H may be disposed on the outer periphery portion of the sheet portion 191 to guide the assembly of the set cover 160 and the shield can 180.

The first insertion portion 192 may extend from the sheet portion 191. The first insertion portion 192 may be disposed corresponding to the other side of the display panel 110. For example, the first insertion portion 192 may be disposed in an area excluding one side where the flexible circuit film COF is disposed of the heat dissipation sheet 190.

The first insertion portion 192 may protrude from the sheet portion 191 toward the set cover 160 and the shield can 180. For example, the first insertion portion 192 may include a vertical portion extending in a first direction and a horizontal portion extending from the vertical portion in a second direction. For example, the first insertion portion 192 may include a vertical portion extending in a direction perpendicular to the sheet portion 191 and a flat portion extending in the same direction as the sheet portion 191 from the vertical portion. The first insertion portion 192 may protrude toward the set cover 160 and the shield can 180 and be coupled to the shield can 180 described below.

Referring to FIG. 3, a plurality of first adhesive layers AD1 may be disposed between the heat dissipation sheet 190 and the shield can 180. The plurality of first adhesive layers AD1 may be disposed corresponding to the outer peripheral areas of the heat dissipation sheet 190 and the shield can 180. For example, the plurality of first adhesive layers AD1 may have a curved shape along the perimeter of the heat dissipation sheet 190 and the shield can 180.

The plurality of first adhesive layers AD1 may be disposed corresponding to a plurality of extension portions 182 of the shield can 180 to be described later. For example, the plurality of first adhesive layers AD1 may be disposed corresponding to second portions 182b of the plurality of extension portions 182.

Meanwhile, the plurality of first adhesive layers AD1 may be disposed in an area except for one side where the flexible circuit film COF is bent of the heat dissipation sheet 190. In addition, the plurality of first adhesive layers AD1 may be disposed in an area except for the other side where the first insertion portion 192 is disposed of the heat dissipation sheet 190. For example, a plurality of first adhesive layers AD1 may be disposed corresponding to both sides of the heat dissipation sheet 190. In this case, the plurality of first adhesive layers AD1 may be disposed to surround the edge of the printed circuit board PCB.

Referring to FIGS. 3 and 4, the shield can 180 is disposed on one surface of the heat dissipation sheet 190. The shield can 180 may include a base portion 181 having a flat shape and the plurality of extension portions 182 extending from the base portion 181 toward the heat dissipation sheet 190.

The base portion 181 may be disposed to overlap at least a portion of the printed circuit board PCB and the flexible circuit film COF disposed on one surface of the heat dissipation sheet 190, and may protect the printed circuit board PCB and the flexible circuit film COF.

The base portion 181 may be disposed spaced apart from the heat dissipation sheet 190 with the plurality of extension portions 182 interposed therebetween, and may also be disposed spaced apart from the flexible circuit film COF and the printed circuit board PCB disposed on one surface of the heat dissipation sheet 190.

The outer peripheral portion of the base portion 181 may include straight portions and curved portions. For example, the base portion 181 may include four straight portions spaced apart from each other and four curved portions connecting the four straight portions.

The base portion 181 may include a plurality of first guide holes 181H. The plurality of first guide holes 181H may be disposed to correspond to a plurality of guide protrusions 163 of the set cover 160 to be described later. Accordingly, the plurality of first guide holes 181H may guide the positions of the set cover 160 and the shield can 180.

The base portion 181 may expose a portion of the flexible circuit film COF. For example, a portion of the flexible circuit film COF may be exposed from one side of the base portion 181.

The plurality of extension portions 182 may extend from the base portion 181. The plurality of extension portions 182 may be disposed corresponding to an area excluding one side of the display panel 110. For example, the plurality of extension portions 182 may be disposed corresponding to the other side and both sides of the display panel 110. For example, the plurality of extension portions 182 may extend from three of the four straight portions forming the outer peripheral portion of the base portion 181, but is not limited thereto.

The extension portion 182 may include a first portion 182a extending in the first direction from the base portion 181 and a second portion 182b extending in the second direction from the first portion 182a.

The first portion 182a may separate the heat dissipation sheet 190 and the base portion 181. For example, the first portion 182a may extend vertically from the base portion 181 and separate the heat dissipation sheet 190 and the base portion 181.

The second portion 182b may extend from the first portion 182a and may be in contact with one surface of the heat dissipation sheet 190. The second portion 182b may include a straight portion corresponding to the outer peripheral portion of the first portion 182a and a curved portion corresponding to the outer peripheral portion of the heat dissipation sheet 190.

Referring to FIGS. 3 and 5, at least one of the plurality of extension portions 182 may include a first hole 182H. For example, an extension portion 182 extending from the other side of the base portion 181 may include the first hole 182H.

The first insertion portion 192 of the heat dissipation sheet 190 may be inserted into the first hole 182H of the shield can 180. Referring to FIG. 7, the portion of the first insertion portion 192 passing through the first hole 182H may be disposed on the second portion 182b. The portion of the first insertion portion 192 passing through the first hole 182H may be disposed on one surface of the second portion 182b and may be disposed so as to overlap a portion of the second portion 182b. Accordingly, the heat dissipation sheet 190 including the first insertion portion 192 may be fixed to the shield can 180 including the first hole 182H. Therefore, the heat dissipation sheet 190 and the shield can 180 may be coupled to each other. Accordingly, when the heat dissipation sheet 190 is attached to the display panel 110 and the shield can 180 is attached to the set cover 160, the set cover 160 and the display panel 110 may be coupled with each other by coupling the heat dissipation sheet 190 and the shield can 180.

In addition, referring to FIG. 3, the remaining plurality of extension portions 182 that does not include the first hole 182H among the plurality of extension portions 182 may be disposed to overlap the plurality of first adhesive layers AD1. For example, the plurality of extension portions 182 extended from both sides of the base portion 181 may be attached to the plurality of first adhesive layers AD1.

Referring to FIGS. 3 and 5, a second adhesive layer AD2 may be disposed on one surface of the shield can 180. The second adhesive layer AD2 may be disposed corresponding to the base portion 181 of the shield can 180. For example, the second adhesive layer AD2 may be disposed overlapping a printed circuit board PCB.

In addition, the outer peripheral portion of the second adhesive layer AD2 may be formed of four straight portions spaced apart from each other and four curved portions connecting the four straight sections. In addition, the second adhesive layer AD2 may include a plurality of second guide holes AD2H corresponding to the plurality of first guide holes 181H. The plurality of guide protrusions 163 of the set cover 160, which will be described later, may be inserted into the plurality of second guide holes AD2H. Accordingly, the plurality of second guide holes AD2H may guide the positions of the set cover 160 and the shield can 180.

Meanwhile, the second adhesive layer AD2 may be disposed so as not to overlap the plurality of first adhesive layers AD1. For example, the extension portions 182 of the shield can 180 may be attached to the heat dissipation sheet 190 through the plurality of first adhesive layers AD1, and the base portion 181 of the shield can 180 may be attached to the set cover 160 through the second adhesive layer AD2.

Referring to FIGS. 3 and 5, the set cover 160 is disposed on one surface of the second adhesive layer AD2. The set cover 160 may accommodate the heat dissipation sheet 190, the shield can 180, the printed circuit board PCB, and the flexible circuit film COF.

The set cover 160 may include a first surface 161 corresponding to the flat shape of the display panel 110, a second surface 162 extending from the first surface 161 and surrounding the side portion of the base portion 181 of the shield can 180, and the plurality of guide protrusions 163 extending from the first surface 161.

Referring to FIGS. 3 and 5, the first surface 161 may have a circular flat shape corresponding to the flat shape of the display panel 110.

Referring to FIG. 5, a thickness T2 of the second surface 162 at a position not overlapping the extension portion 182 may be thinner than the thickness T2 of the second surface 162 at a position overlapping the extension portion 182. Accordingly, referring also to FIG. 3, it can be confirmed that the thickness T2 of the second surface 162 at an area overlapping the flexible circuit film COF is thinner than a thickness T1 of the second surface 162 at an area corresponding to the first insertion portion 192 of the heat dissipation sheet 190. Accordingly, even when the flexible circuit film COF is disposed to overlap the set cover 160, the flexible circuit film COF may not interfere with the shield can 180, and the contact between the flexible circuit film COF and the set cover 160 may be suppressed.

Referring to FIGS. 5 and 6, the set cover 160 may include the plurality of guide protrusions 163. The plurality of guide protrusions 163 may protrude from the first surface 161 in the direction in which the heat dissipation sheet 190 is disposed. Referring to FIG. 6, the plurality of guide protrusions 163 may be inserted into the plurality of second guide holes AD2H of the second adhesive layer AD2 and the plurality of first guide holes 181H of the shield can 180. Accordingly, the plurality of guide protrusions 163 may guide the attachment positions of the shield can 180 and the set cover 160.

Research is being conducted on display apparatus having various shapes for aesthetics and usability. For example, research is being conducted on small display apparatus. However, when the display apparatus is miniaturized, there is a problem in that the fastening space and bonding area for fixing the display panel, heat dissipation sheet, and set cover that constitute the display apparatus become narrow. For example, the heat dissipation sheet may be disposed on one surface of the display panel and may be fully attached to one surface of the display panel through the adhesive layer. However, in the case of the set cover, in order to suppress interference with the flexible circuit film and the printed circuit board, the display panel and the heat dissipation sheet should be fastened in an area that does not overlap the flexible circuit film and the printed circuit board. Accordingly, when the display apparatus is miniaturized, there is a problem in that the area that does not overlap the flexible circuit film and the printed circuit board decreases, and the fastening space between the set cover, the display panel, and the heat dissipation sheet may become narrow. Accordingly, the fastening force of the display panel, the heat dissipation sheet, and the set cover may be reduced, which may cause assembly failure, and the display panel, the heat dissipation sheet, and the set cover may become lifted.

Accordingly, the display apparatus 100 according to one exemplary embodiment of the present disclosure may reinforce the fixing force of the heat dissipation sheet 190 and the set cover 160 by placing the shield can 180 between the heat dissipation sheet 190 and the set cover 160. For example, the shield can 180 includes the base portion 181 attached to the set cover 160 and the plurality of extension portions 182 attached to the heat dissipation sheet 190. The base portion 181 may be attached to the set cover 160 via the second adhesive layer AD2 in the area overlapping the flexible circuit film COF and the printed circuit board PCB. The extension portion 182 may be attached to the heat dissipation sheet 190 via the plurality of first adhesive layers AD1 in the area not overlapping the flexible circuit film COF and the printed circuit board PCB. Accordingly, compared to a case where the shield can 180 is directly attached to the heat dissipation sheet 190 in the area where the shield does not overlap the flexible circuit film COF and the printed circuit board PCB, it is possible to increase the fixing force between the shield can 180 and the heat dissipation sheet 190. Accordingly, the problem of components such as the display panel 110, the shield can 180, and the heat dissipation sheet 190 constituting the display apparatus 100 being lifted may be minimized.

According to one exemplary embodiment of the present disclosure, the display apparatus 100 may increase the fixing force between the heat dissipation sheet 190 and the shield can 180 by inserting the first insertion portion 192 of the heat dissipation sheet 190 into the first hole 182H of the shield can 180. For example, the first insertion portion 192 of the heat dissipation sheet 190 may be inserted into the first hole 182H of the shield can 180 and disposed on the extension portion 182 of the shield can 180. Accordingly, the extension portion 182 and the first insertion portion 192 may be fastened to each other to increase the fixing force between the heat dissipation sheet 190 and the shield can 180. Accordingly, the fixing force between the display panel 110 attached to the heat dissipation sheet 190 and the set cover 160 attached to the shield can 180 may be increased.

In addition, the display apparatus 100 according to one exemplary embodiment of the present disclosure may suppress incorrect assembly of the display apparatus 100 by including the heat dissipation sheet 190 including the plurality of grooves 191H and the set cover 160 including the plurality of guide protrusions 163. In the case of a circular display apparatus, it is difficult to align the positions of the display panel, the heat dissipation sheet, the shield can, and the set cover constituting the display apparatus. Accordingly, a problem may occur in which the display panel, the heat dissipation sheet, the shield can, and the set cover are assembled in a rotated state. In response to this, the display apparatus 100 according to one exemplary embodiment of the present disclosure may align the positions of the heat dissipation sheet 190, the shield can 180, and the set cover 160 by disposing the plurality of grooves 191H on the outer peripheral portion of the heat dissipation sheet 190. In addition, the display apparatus 100 according to one exemplary embodiment of the present disclosure may align the positions of the shield can 180 and the set cover 160 by disposing the plurality of guide protrusions 163 on the set cover 160. Therefore, the display apparatus 100 according to one exemplary embodiment of the present disclosure may suppress the incorrect assembly problem that may occur in the circular display apparatus 100.

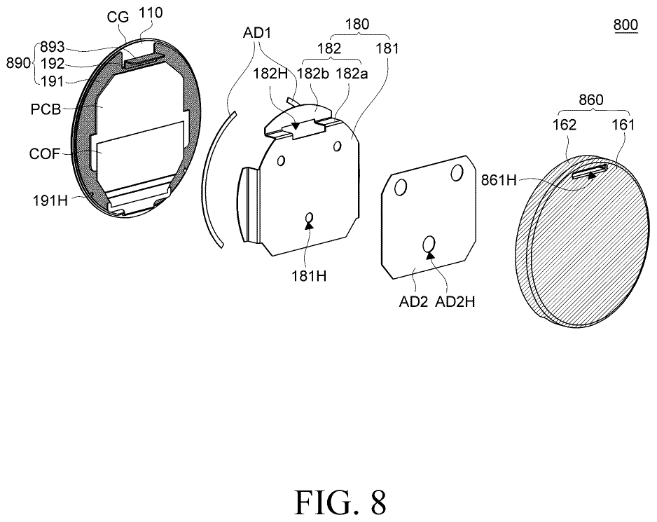

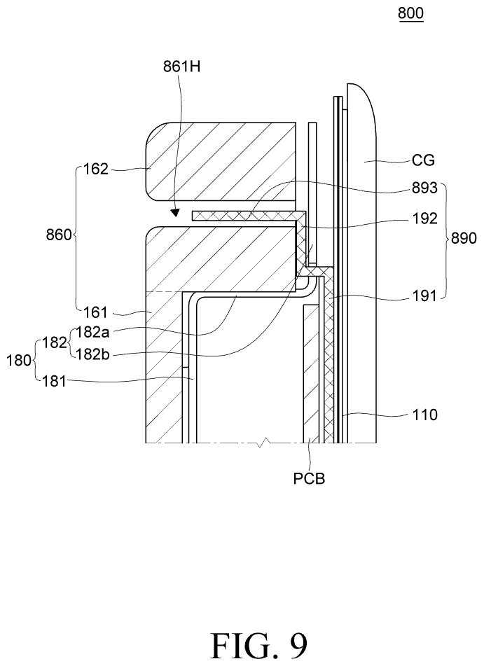

FIG. 8 is an exploded perspective view of a display apparatus according to another exemplary embodiment of the present disclosure. FIG. 9 is a cross-sectional view of the display apparatus according to another exemplary embodiment of the present disclosure. A display apparatus 800 of FIG. 8 is different from the display apparatus 100 of FIGS. 1 to 6 only in that a second insertion portion 893 is added to a heat dissipation sheet 890 and a second hole 860H is added to a set cover 860, and since the other configurations are substantially the same, a duplicate description is omitted.

Referring to FIG. 8, the heat dissipation sheet 890 may include a sheet portion 191, a first insertion portion 192 extending from the sheet portion 191, and a second insertion portion 893 extending from the first insertion portion 192.

The second insertion portion 893 may extend from the first insertion portion 192 toward the set cover 860. The second insertion portion 893 may extend toward the set cover 860 and be inserted into the second hole 860H of the set cover 860.

The set cover 860 may include a first surface 161, a second surface 162 extending from the first surface 161, a plurality of guide protrusions 163 extending from the first surface 161, and a second hole 860H.

The second hole 860H may open a portion of the first surface 161 and the second surface 162. A portion of the heat dissipation sheet 890 may be inserted into the second hole 860H of the set cover 860. Referring to FIG. 9, the second insertion portion 893 of the heat dissipation sheet 890 may be inserted into the second hole 860H. Accordingly, the second insertion portion 893 passing through the second hole 860H may be fixed to the set cover 860 including the second hole 860H. Accordingly, the heat dissipation sheet 890 and the set cover 860 may be coupled to each other.

The display apparatus 800 according to another exemplary embodiment of the present disclosure includes the base portion 181 to which the shield can 180 is attached to the set cover 860 and the plurality of extension portions 182 attached to the heat dissipation sheet 890. Accordingly, compared to a case where the shield can 180 is directly attached to the heat dissipation sheet 890, the fixing force between the shield can 180 and the heat dissipation sheet 890 may increase, and the problem of components constituting the display apparatus 800 being lifted may be minimized.

The display apparatus 800 according to another exemplary embodiment of the present disclosure may increase the fixing force between the heat dissipation sheet 890 and the shield can 180 by inserting the first insertion portion 192 of the heat dissipation sheet 890 into the first hole 182H of the shield can 180.

The display apparatus 800 according to another exemplary embodiment of the present disclosure may suppress incorrect assembly of the display apparatus 800 by including the heat dissipation sheet 890 including the plurality of grooves 191H and the set cover 860 including the plurality of guide protrusions 163.

The display apparatus 800 according to another exemplary embodiment of the present disclosure may increase the fixing force of the heat dissipation sheet 890 and the set cover 860 by inserting the second insertion portion 893 of the heat dissipation sheet 890 into the second hole 860H of the set cover 860. For example, the first insertion portion 192 and the second insertion portion 893 of the heat dissipation sheet 890 may be inserted into the first hole 182H of the shield can 180, and the second insertion portion 893 that passes through the first hole 182H of the shield can 180 may also pass through the second hole 860H of the set cover 860. Accordingly, the fixing force of the heat dissipation sheet 890, the shield can 180, and the set cover 860 may be improved, and the fixing force between the display panel 110 attached to the heat dissipation sheet 890 and the set cover 860 attached to the shield can 180 may be improved.

The exemplary embodiments of the present disclosure can also be described as follows:

According to an aspect of the present disclosure, there is provided a display apparatus. The display apparatus comprises a display panel, a heat dissipation sheet disposed on the display panel, a shield can disposed on the heat dissipation sheet, and a set cover disposed on the shield can, wherein the heat dissipation sheet includes a sheet portion and a first insertion portion protruding from the sheet portion toward the set cover and coupled with the shield can, the shield can includes a base portion having a flat shape, and a plurality of extension portions including a first portion extending in a first direction from the base portion toward the heat dissipation sheet and a second portion extending in a second direction different from the first direction from the first portion, at least one of the plurality of extension portions includes a first hole into which the first insertion portion is inserted, and a portion of the first insertion portion passing through the first hole is disposed on the second portion.

The display apparatus may further comprise a plurality of first adhesive layers for attaching the heat dissipation sheet and the shield can, and a second adhesive layer for attaching the shield can and the set cover, the second adhesive layer not overlapping the plurality of first adhesive layers.

The display apparatus may further comprise a flexible circuit film connected to the display panel and bent at one side of the display panel and disposed between the heat dissipation sheet and the shield can, wherein the first insertion portion may be disposed corresponding to the other side of the display panel.

The plurality of extension portions may be disposed corresponding to an area excluding the one side of the display panel.

The set cover may include a first surface corresponding to a flat shape of the display panel, and a second surface extending from the first surface and surrounding a side portion of the base portion, and a thickness of the second surface in an area overlapping the flexible circuit film may be thinner than a thickness of the second surface in an area corresponding to the first insertion portion.

The set cover may include a second hole, and the heat dissipation sheet may further include a second insertion portion extending from the first insertion portion and inserted into the second hole.

The set cover may include a plurality of guide protrusions to guide attachment positions of the shield can and the set cover, and the base portion may include a plurality of guide holes corresponding to the plurality of first guide protrusions.

The first direction may be a direction perpendicular to the base portion, and the second direction may be the direction extending from the first portion toward an outer periphery portion of the base portion.

The sheet portion of the heat dissipation sheet may include a plurality of grooves, and the plurality of grooves are disposed on an outer periphery portion of the sheet portion to guide the assembly of the set cover and the shield can.

The second adhesive layer may include a plurality of second guide holes corresponding to the plurality of first guide holes, and the plurality of guide protrusions of the set cover are inserted into the plurality of second guide holes.

According to another aspect of the present disclosure, there is provided a display apparatus. The display apparatus comprises a display panel, a heat dissipation sheet disposed on the display panel and including a first insertion portion, a printed circuit board electrically connected to the display panel and disposed on the heat dissipation sheet, a shield can disposed on the printed circuit board and including a first hole into which the first insertion portion is inserted, and a set cover disposed on the shield can, wherein at least a portion of the first insertion portion extends onto the shield can and overlaps a portion of the shield can.

The display apparatus may further comprise a plurality of first adhesive layers disposed to surround an edge of the printed circuit board between the heat dissipation sheet and the shield can, and a second adhesive layer disposed to overlap the printed circuit board between the shield can and the set cover.

The shield can may include a base portion, and a plurality of extension portions extending from the base portion toward the heat dissipation sheet, and at least one of the plurality of extension portions may include the first hole, and remaining extension portions of the plurality of extension portions may be attached to the plurality of first adhesive layers.

The display apparatus may further comprise a flexible circuit film connected to one side of the display panel, wherein the plurality of extension portions may be disposed corresponding to an area excluding the one side of the display panel.

The set cover may include a plurality of guide protrusions protruding in a direction in which the heat dissipation sheet is disposed, and the shield can may include a plurality of guide holes corresponding to the plurality of first guide protrusions.

The set cover may include a second hole into which a portion of the heat dissipation sheet is inserted.

The heat dissipation sheet may further include a second insertion portion extending from the first insertion portion and inserted into the second hole.

The heat dissipation sheet may include a plurality of grooves, and the plurality of grooves are disposed on an outer periphery portion of the sheet portion to guide the assembly of the set cover and the shield can.

The second adhesive layer may include a plurality of second guide holes corresponding to the plurality of first guide holes, and the plurality of guide protrusions of the set cover are inserted into the plurality of second guide holes.

It will be apparent to those skilled in the art that various modifications and variations can be made in the display apparatus of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display apparatus, comprising:
a display panel;
a heat dissipation sheet disposed on the display panel;
a shield can disposed on the heat dissipation sheet; and
a set cover disposed on the shield can,
wherein the heat dissipation sheet includes a sheet portion and a first insertion portion protruding from the sheet portion toward the set cover and coupled with the shield can,
wherein the shield can includes:
a base portion having a flat shape, and
a plurality of extension portions including a first portion extending in a first direction from the base portion toward the heat dissipation sheet and a second portion extending in a second direction different from the first direction from the first portion,
wherein at least one of the plurality of extension portions includes a first hole into which the first insertion portion is inserted, and
wherein a portion of the first insertion portion passing through the first hole is disposed on the second portion.

2. The display apparatus according to claim 1, further comprising:
a plurality of first adhesive layers for attaching the heat dissipation sheet and the shield can; and
a second adhesive layer for attaching the shield can and the set cover, the second adhesive layer not overlapping the plurality of first adhesive layers.

3. The display apparatus according to claim 1, further comprising a flexible circuit film connected to the display panel and bent at one side of the display panel and disposed between the heat dissipation sheet and the shield can,
wherein the first insertion portion is disposed corresponding to the other side of the display panel.

4. The display apparatus according to claim 3, wherein the plurality of extension portions is disposed corresponding to an area excluding the one side of the display panel.

5. The display apparatus according to claim 3, wherein the set cover includes
a first surface corresponding to a flat shape of the display panel, and
a second surface extending from the first surface and surrounding a side portion of the base portion, and
a thickness of the second surface in an area overlapping the flexible circuit film is thinner than a thickness of the second surface in an area corresponding to the first insertion portion.

6. The display apparatus according to claim 1, wherein the set cover includes a second hole, and
the heat dissipation sheet further includes a second insertion portion extending from the first insertion portion and inserted into the second hole.

7. The display apparatus according to claim 2, wherein the set cover includes a plurality of guide protrusions to guide attachment positions of the shield can and the set cover, and
the base portion includes a plurality of first guide holes corresponding to the plurality of guide protrusions.

8. The display apparatus according to claim 1, wherein the first direction is a direction perpendicular to the base portion, and the second direction is the direction extending from the first portion toward an outer periphery portion of the base portion.

9. The display apparatus according to claim 1, wherein the sheet portion of the heat dissipation sheet includes a plurality of grooves, and the plurality of grooves are disposed on an outer periphery portion of the sheet portion to guide an assembly of the set cover and the shield can.

10. The display apparatus according to claim 7, wherein the second adhesive layer includes a plurality of second guide holes corresponding to the plurality of first guide holes, and the plurality of guide protrusions of the set cover are inserted into the plurality of second guide holes.

11. A display apparatus, comprising:
a display panel;
a heat dissipation sheet disposed on the display panel and including a first insertion portion;
a printed circuit board electrically connected to the display panel and disposed on the heat dissipation sheet;
a shield can disposed on the printed circuit board and including a first hole into which the first insertion portion is inserted; and
a set cover disposed on the shield can,
wherein at least a portion of the first insertion portion extends onto the shield can and overlaps a portion of the shield can.

12. The display apparatus according to claim 11, further comprising a plurality of first adhesive layers disposed to surround an edge of the printed circuit board between the heat dissipation sheet and the shield can; and
a second adhesive layer disposed to overlap the printed circuit board between the shield can and the set cover.

13. The display apparatus according to claim 12, wherein the shield can includes a base portion, and a plurality of extension portions extending from the base portion toward the heat dissipation sheet, and
wherein at least one of the plurality of extension portions include the first hole, and remaining extension portions of the plurality of extension portions are attached to the plurality of first adhesive layers.

14. The display apparatus according to claim 13, further comprising a flexible circuit film connected to one side of the display panel,
wherein the plurality of extension portions is disposed corresponding to an area excluding the one side of the display panel.

15. The display apparatus according to claim 12, wherein the set cover includes a plurality of first guide protrusions protruding in a direction in which the heat dissipation sheet is disposed, and
the shield can includes a plurality of guide holes corresponding to the plurality of first guide protrusions.

16. The display apparatus according to claim 11, wherein the set cover includes a second hole into which a portion of the heat dissipation sheet is inserted.

17. The display apparatus according to claim 16, wherein the heat dissipation sheet further includes a second insertion portion extending from the first insertion portion and inserted into the second hole.

18. The display apparatus according to claim 11, wherein the heat dissipation sheet includes a plurality of grooves, and the plurality of grooves are disposed on an outer periphery portion of the dissipation sheet to guide an assembly of the set cover and the shield can.

19. The display apparatus according to claim 15, wherein the second adhesive layer includes a plurality of second guide holes corresponding to the plurality of first guide holes, and the plurality of guide protrusions of the set cover are inserted into the plurality of second guide holes.
